(19) United States
(12) Patent Application Publication
(10) Pub. No.: US 2024/0340015 A1
(43) Pub. Date: Oct. 10, 2024

(54) UTILIZE THE VOLTAGE-CONTROLLED OSCILLATOR TO CONTINUOUSLY OUTPUT SIGNAL WITH ACCEPTABLE FREQUENCY WITHOUT UTILIZING PHASE LOCK LOOP

(71) Applicant: HORNG TONG ENTERPRISE CO., LTD., New Taipei City (TW)

(72) Inventors: Chia-Ming Liang, New Taipei City (TW); Chun-Te Lin, New Taipei City (TW); Zong-You Li, New Taipei City (TW)

(21) Appl. No.: 18/132,454

(22) Filed: Apr. 10, 2023

(51) Int. Cl. H03L 7/18; H03L 7/197

(52) U.S. Cl. CPC H03L 7/1803; H03L 7/197

(57) ABSTRACT

The present invention continuously generates a signal at an acceptable frequency without utilizing the PLL to modify the operation of the VCO. When the VCO is initialized properly to output a signal at a specific frequency, the VCO operates on its own to continuously output signals, and the VCO state is modified at regular intervals. Thus, when the interval is short enough and when the VCO is modified to the initial state every time, the VCO state will not deviate significantly from the initial state during these intervals. Thus, the VCO continuously generate signals with frequencies acceptably closed to the specific frequency. That is to say, the invention utilizes the injection lock to modify the operation of the VCO. To compare with the convention skills utilizing the PLL which has to feed back the signal generated by the VCO to the PLL for modifying the VCO state dynamically, the utilization of the injection lock simplifies the hardware and streamlines the process. Thus, the invention is an alternation to the convention technologies with lower cost and similar accuracy.

### FIELD OF THE INVENTION

The invention is related to utilize a voltage-controlled oscillator (VCO) to continuously output signal at acceptable frequency during an operation period, in specific, to utilize the injection lock but not the phase lock loop to modify the operation of the VCO to continuously output signal at acceptable frequency during a period.

### BACKGROUND OF THE INVENTION

In electronic circuit design, different parts of the circuit often require different signals of different frequencies. One common approach is to utilize the frequency synthesizer with the VCO in different parts of the circuit so as to convert the same input signal into different signal with different frequencies respectively. However, this approach requires complex circuitry to modify the operation of the VCO. Also, the energy consumption, the occupied wafer area and the design difficulty are proportional to the frequency of the signal outputted by the VCO output, which is increasingly serious with the development of satellite communication, 5G wireless communication and so on.

For example, a common type of frequency synthesizer utilizes a phase-locked loop (PLL) to adjust the signal output from the VCO. As shown in FIG. 1A, the PLL 11 is electrically connected to the VCO 12. The PLL 11 receives both the input signal Sin and the signal Sout outputted by the VCO 12, and then generate the control signal Sctrl accordingly. Basically, as shown in FIG. 1B, it is a feedback control system. The input signal Sin is received by the divider 13 that divides the frequency of the input signal Sin by an integer R. The output of the divider 13 is the reference signal that forms one input to the phase frequency detector (PFD) 14. The other input to the PFD 14 is the return signal from the output of the divider counter 18 that divides the frequency of the output signal Sout by an integer N. Under normal conditions, if the PLL is locked, the frequencies of these two signals are almost equivalent. The output of the PFD 14 is a voltage whose magnitude is proportional to the phase difference between the two inputs. At initialization or when the input has a large instantaneous frequency offset, the PLL is not locked and the PFD 14 directs the PLL to operate at the desired setting. Once the desired frequency is reached, the PFD 14 returns to the phase detector mode, and then its output is proportional to the phase difference between the reference signal and the return signal. The PFD 14 drives the charge pump 15 to output positive and negative current pulses to the loop filter 16. This loop filter 16 smooths the related signal which determines the dynamic characteristics of the PLL. Notice that the frequency of the output signal Sout outputted by the VCO is N times the frequency of the return signal provided to the PFD 14, i.e. N/R times the frequency of the input signal Sin. This output signal is passed back to the PFD 14 through the divider 18 as a N division counter.

Significantly, there is a strong requirement to simplify the hardware and the method for modifying the operation of the VCO according to the input signal, so as to at least reduce hardware cost, save occupied wafer area and enhance frequency adjustment efficiency.

### SUMMARY OF THE INVENTION

The basic concept of the present invention is to use injection lock instead of PLL to modify the operation of the VCO. In short, after initializing the VCO to an initial state in which the VCO outputs a specific signal at a specific frequency, the VCO continuously operates on its own while the VCO receives control signals to modify its state toward the initial state at regular intervals. Clearly, the action of inputting the control signals to the VCO may be viewed as injection, and the result of modifying the VCO operation according to the control signal may be viewed as lock (lock the VCO state).

Significantly, one main feature of the proposed invention is that the signal outputted by the VCO is not feedback to modify the operation of the VCO. Another main feature of the proposed method is that the operation of the VCO is modified at regular or pre-determined intervals such that the output signal of the VCO is adjusted intermittently. In other words, after the operation of the VCO is properly modify to an initial state that precisely output the specific signal at the specific frequency, the operation of the VCO is not limited during the specific period. It may be viewed as the operation of the VCO is not modified by receiving any control signal during the specific period. Thus, the frequency of the signal outputted by the VCO may be different than the specific frequency during the specific period, wherein the frequency differences therebetween may be a result of many factors including but not limited to the specific frequency, the specific period, the hardware quality of the VCO, and the external noise. Anyway, at the end of the specific period, no matter how the practical state of the VCO is or viewed as how the frequency of the signal outputted by the VCO is, the operation of the VCO is modified again by receiving a control signal that is designed to make the VCO output the specific signal at the specific frequency. Thus, the practical state of the VCO may be adjusted back to be the initial state, at least may be adjusted to be closed to the initial state. Thus, the frequency of the signal outputted by the VCO may be adjusted to be, or at least closed to, the specific frequency again. Therefore, by repeating the step of operating the VCO on its own and the step of modifying the operation of the VCO during an operation period including a number of specific periods, the frequency of the signal outputted by the VCO may be maintained in an acceptable range. Surely, the specific period is an adjustable parameter. For example, by using a counter to trace the practical frequency of the signal outputted by the VCO, the specific period may be shortened if the frequency difference is larger than a threshold at the end of the specific period, and versa.

Based on the basic concept, the invention provides a method of utilizing a VCO to continuously provide a signal at an acceptable frequency during an operation period of the VCO. Initially, initialize the VCO so that the VCO outputs a specific signal at a specific frequency. Next, operate the VCO on its own for a specific period. And then, at the end of the specific period, inputting a control signal to the VCO to modify the operation of the VCO, wherein the control signal is designed to make the VCO output the specific signal at the specific frequency. Surely, the latter two steps can be repeatedly interleaved

Based on the basic concept, the invention also provides a frequency synthesizer capable of generating a specific signal at a specific frequency without utilizing a phase lock loop. The frequency synthesizer has an injection lock module and a VCO. The former is configured to receive an input signal and then generate a control signal correspondingly, and the latter is configured to receive the control signal and then output an output signal. Moreover, the output signal is not feedback to the injection lock module for generating the control signal correspondingly.

Based on the basic concept, the invention still provides a method of utilizing a frequency synthesizer without phase lock loop to continuously provide a signal at acceptable frequency during an operation period. Initially, utilize an injection lock module to receive an input signal and then generate a control signal correspondingly. Next, utilize a VCO to receive the control signal and then output a specific signal at a specific frequency correspondingly. Wherein, the injection lock module modifies the operation of the VCO during the operation period of the VCO without receiving the specific signal.

The effect of the present invention compared with the conventional technology is that the present invention can at least reduce the hardware cost, save the occupied wafer area, and improve the efficiency of VCO modification. The injection lock used in the present invention requires only periodic input control signals to the VCO to modify the operation of the VCO periodically. The used injection lock also need not feedback output signals of the VCO to adjust the control signals correspondingly. Therefore, the present invention requires fewer and simpler circuit elements to implement it than the conventional techniques that use PLLs to modify VCO operation. Therefore, not only the occupied wafer area can be reduced, but also the related manufacturing process can be simplified. Also, the energy consumed during VCO operation can be reduced. Note that the occupied wafer area and the consumed power of a PLL is proportional to the frequency of the signal to be outputted by the VCO. As a result, the various costs of using the present invention can be reduced.

### BRIEF DESCRIPTION OF THE DRAWINGS

FIG. 1A to FIG. 1B are a two functional modules drawings illustrating the convention technologies.

FIG. 2 is an essential flowchart of a present method utilizing a VCO without utilizing phase lock loop.

FIG. 3A is an essential functional structure of a present frequency synthesizer without phase lock loop, and FIG. 3B to FIG. 3C are two functional structures of two options of the present frequency synthesizer without phase lock loop respectively.

FIG. 4 is an essential functional structure of a present method utilizing a frequency synthesizer without utilizing phase lock loop.

FIG. 5 is a layout of a commercial frequency synthesizer utilizing a phase lock loop.

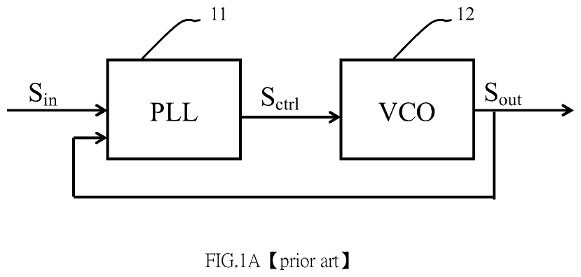

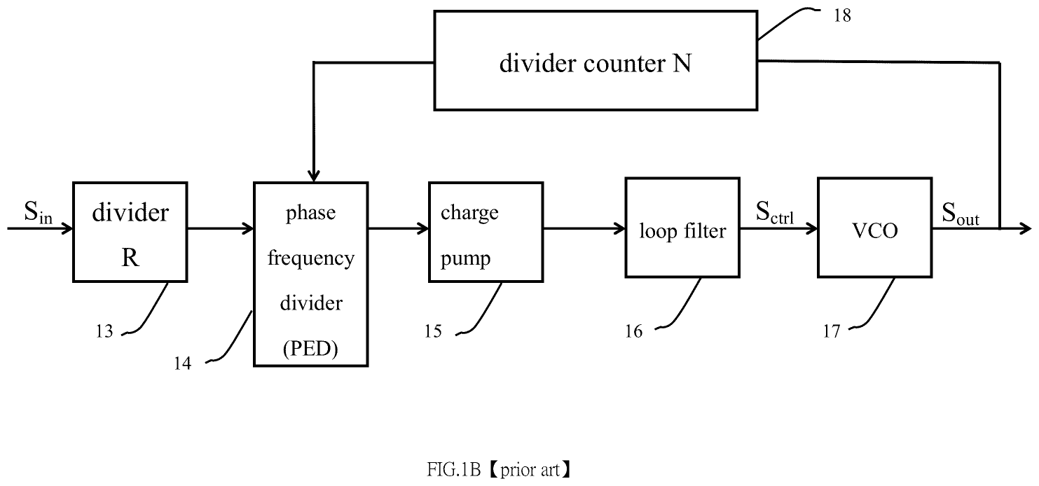

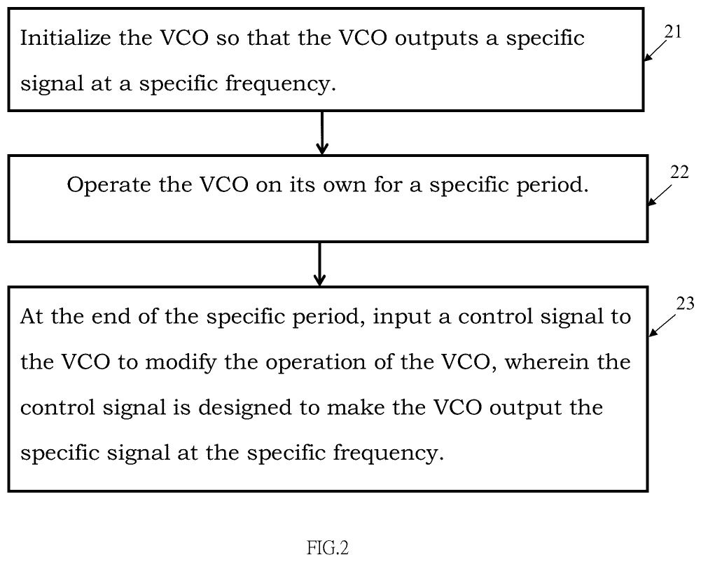

### DETAILED DESCRIPTION OF THE INVENTION

The detailed description and preferred embodiments of the invention are set forth in the following content and provided for people skilled in the art to understand the characteristics of the invention.

The invention presents a method of utilizing a VCO to continuously provide a signal at an acceptable frequency during an operation period of the VCO. As the essential flowchart shown in FIG. 2, the method has the following essential steps. Initially, as shown in block 21, initialize the VCO so that the VCO outputs a specific signal at a specific frequency. Next, as shown in block 22, operate the VCO on its own for a specific period. And then, as shown in block 23, at the end of the specific period, input a control signal to the VCO to modify the operation of the VCO, wherein the control signal is designed to make the VCO output the specific signal at the specific frequency.

Significantly, the present method does not dynamically modify the operation of the VCO to continuously output a specific signal at a specific frequency over a specific period, but rather adjust the frequency of the output signal at the end of the specific period. Therefore, the present method need not to feedback the VCO output signal to modify the VCO state, also the VCO is operated without receiving any control signal during the specific period. Besides, how to adjust the control signal to adjust the frequency of the output signal is independent on the frequency of the output signal. In contrast, the conventional technologies continuously modify the operation of the VCO so as to dynamically adjust the output signal of the VCO. Particularly, the conventional technologies utilizing PLL must feedback the signal outputted by to VCO to the PLL such that the PLL may modify the operation of the VCO according to at least the frequency of the output signal.

Of course, to further continuously provide a signal at an acceptable frequency during a longer period, such as the operation period of the VCO including numerous specific periods, the step of operating the VCO on its own for a specific period and the step of inputting a control signal to the VCO to modify the operation of the VCO at the end of the specific interval in a regular manner are repeated. Indeed, if necessary, they may be repeated in an irregular manner.

Surely, in the process of repeating these two steps, there are two options to further ensure that the frequency of the output signal is acceptable (or viewed as the difference between the specific frequency and the frequency of the output signal is acceptable). One is that adjust the specific period of operating the VCO after the operation of the VCO has been modified according to the control signal and before the VCO operates on its own again. Another is that and adjust the control signal after the VCO has operated on its own again and before the operation of the VCO is modified again.

In general, the control signal is a square wave, wherein the strength of the square wave is proportional to the frequency of the specific signal and wherein the width of the square wave is proportional to the strength of the specific signal. Also, output power of the VCO gradually enters a steady state as the time gets longer. That is to say, regardless of the signal source, it is better to digitize the control signal before inputting it to the VCO, because the digitized control signal is beneficial for more precise regulation of the VCO's operation. Surely, another advanced version is that the control signal is a series of square waves, wherein the strength of each square wave is proportional to the frequency of the specific signal, and wherein the width of each square wave is proportional to the strength of the specific signal. Again, output power of the VCO gradually enters a steady state as the time gets longer. Moreover, during the operation period of the VCO, in order to offset any changes in the VCO and stabilize the output signal of the VCO, different square waves may have different strengths, different square waves may have different widths, and different time periods between different square waves may be non-consistent. Thus, no matter the required specific frequency is drastically changer or occasional external noises appear, even occasional VCO hardware defects affect the operation of the VCO, the method still is workable.

In additional, to initialize the VCO, because the popular hardware design of the VCO contains several parallel capacitors, one popular option is to adjust he capacitance of at least one capacitor so as to make the VCO output the specific signal before the VCO operates on its own for the specific period.

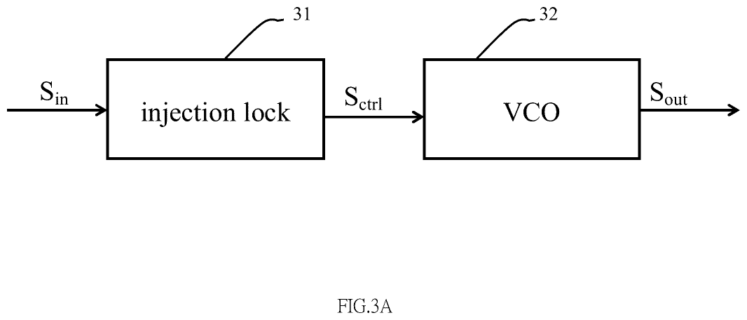

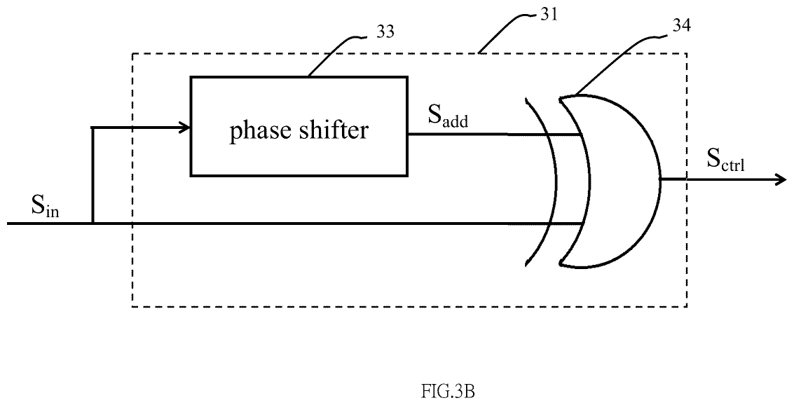

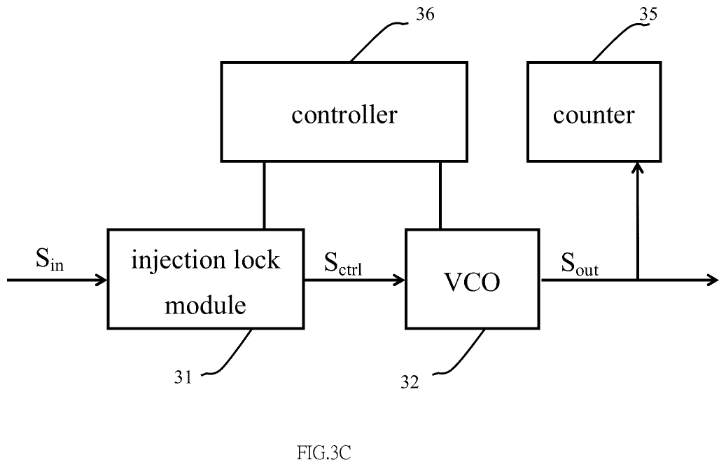

The invention presents a frequency synthesizer capable of generating a specific signal at a specific frequency without utilizing phase lock loop. As the essential functional structure shown in FIG. 3A, the present frequency synthesizer has the following essential portions: the injection lock mode 31 and the VCO 32. The injection lock module 31 is configured to receive an input signal Sin and then generate a control signal Sctrl correspondingly, and the VCO 32 is configured to receive the control signal Sctrl and then output an output signal Sout correspondingly. Moreover, the output signal Sout is not feedback to the injection lock module 31 for generating the control signal Sctrl correspondingly.

Significantly, the present frequency synthesizer utilizes the injection lock mechanism and the method of utilizing a VCO to continuously provide a signal at an acceptable frequency during an operation period of the VCO as described above. Hence, the relative details are not repeatedly described herein.

In short, the injection lock module 31 is generally configured to generate the control signal as a series of square waves, wherein the strength and the width of each of these square waves are proportional to the frequency and the strength of the specific signal respectively, and wherein output power of the VCO gradually enters a steady state as the time gets longer. Of course, the injection lock module 31 may be configured to generate the control signal as a series of analog signals approximating digital signals, as long as the frequency of the output signal is within an acceptable range for the operation period of the VCO 32 (or viewed as the operation period of the frequency synthesizer).

One popular configuration of the injection lock module 31 is utilizing the pulse width modulation (PWM) technology to convert the input signal into the control signal as a series of square waves. Because the PWM technology is well-known, any existed, on-developing or to-be-appeared circuits capable of implementing the PWM technology is acceptable, and then the proposed frequency synthesizer is not limited thereto.

Anyway, other configuration of the injection lock module 31 is acceptable. For example, the injection lock module 31 may be a combination of the phase shifter 33 and the XOR gate 34, as shown in FIG. 3B. The phase shifter 33 is configured to delay the phase of the input signal Sin by a specific delay period for generating an additional signal Sadd, and the XOR gate 34 is configured to receive both the input signal Sin and the additional signal Sadd and then correspondingly generate the control signal Sctrl to be inputted to the VCO 32. Optionally, the specific delay period is inversely proportional to the specific frequency of the specific signal.

Optionally, as shown in FIG. 3C, the frequency synthesizer may further comprise the counter 35 and the controller 36. The counter 35 is configured to detect the frequency of the signal outputted by the VCO 32 when the VCO 32 is initialized. The controller 35 is configured to adjust the capacitance of at least one capacitor of the VCO 32 so as to modify the initialization of the VCO 32 to generate the specific signal at the specific frequency according to the detected frequency sent from the counter 35. Moreover, the injection lock module is 31 configured to generates a series of square waves so as to modify the operation of the VCO 32 during the operation period of the VCO 32 correspondingly, wherein the strength and the width of each of these square waves is proportional to the specific frequency and the strength of the specific signal respectively. As time gets long, output power of the VCO is gradually steadily. Also, the controller 35 is configured to modify the operation of the injection lock module 31 so as to modify the width of each of these square waves.

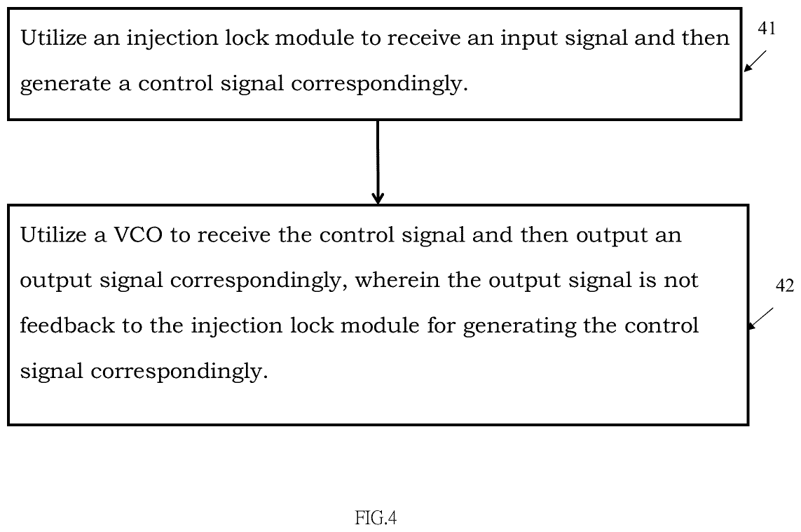

The invention presents a method utilizing a frequency synthesizer without phase lock loop to continuously provide a signal at acceptable frequency during an operation period. As the essential functional structure shown in FIG. 4, the method has the following essential steps. Initially, as shown in block 41, utilize an injection lock module to receive an input signal and then generate a control signal correspondingly. And then, as shown in block 42, utilize a VCO to receive the control signal and then output an output signal correspondingly, wherein the output signal is not feedback to the injection lock module for generating the control signal correspondingly.

Significantly, the present frequency synthesizer utilizes the injection lock mechanism, the method of utilizing a VCO to continuously provide a signal at an acceptable frequency during an operation period of the VCO, and a frequency synthesizer capable of generating a specific signal at a specific frequency without utilizing phase lock loop as described above. Hence, the relative details are not repeatedly described herein.

In general, to properly modify the operation of the VCO, utilize the injection lock module to generate the control signal as a series of square waves, wherein the strength and the width of each of these square waves are proportional to the frequency and the strength of the specific signal respectively. Anyway, it is acceptable to utilize the injection lock module to generate the control signal as a series of analog signals approximating digital signals, as long as the frequency of the output signal is within an acceptable range for the operation period of the VCO (or viewed as the operation period of the frequency synthesizer).

How the injection lock module utilizes converts the input signal into the control signal as a series of square waves is not limited, wherein the strength and the width of each of these square waves are proportional to the frequency and the strength of the specific signal respectively and output power of the VCO gradually enters a steady state as the time gets longer. As usual, the injection lock module 31 utilizes the pulse width modulation (PWM) technology to implement it, because the PWM technology is well-known and there are many available commercial designs may be used. Indeed, any existed, on-developing or to-be-appeared circuits capable of implementing the PWM technology is acceptable, and then the proposed frequency synthesizer is not limited thereto. As an extra example, utilize a phase shifter and a XOR gate to implement the injection lock module. The phase shifter may delay the phase of the input signal by a specific delay period for generating an additional signal, and the XOR gate may receive both the input signal and the additional signal and then outputs the control signal to the VCO. Wherein, the specific delay period may be inversely proportional to the required frequency of the specific signal.

Optionally, the method may utilize a counter to detect the frequency of a signal outputted by the VCO when the VCO is initialized. And, the method may utilize the controller to adjust the capacitance of at least one capacitor of the VCO so as to modify the initialization of the VCO to generate the specific signal at the specific frequency. Also, the method may utilize the injection lock module to generates a series of square waves so as to modify the operation of the VCO during the operation period of the VCO correspondingly, wherein the strength and the width of each of these square waves is proportional to the specific frequency and the strength of the specific signal respectively, also wherein output power of the VCO gradually enters a steady state as the time gets longer. In addition, the method may utilize the controller to modify the operation of the injection lock module so as to adjust the width of each of these square waves.

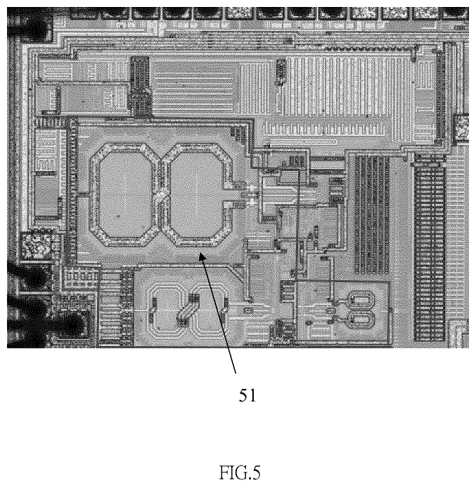

The benefits of the proposed invention may be further illustrated by the following examples. First example is a layout of a commercial frequency synthesizer utilizing the PLL, as shown in FIG. 5, wherein the specially framed area 51 corresponds to the PLL and occupies a significant portion of the wafer area. Hence, when the invention does not the use the PLL but use an injection lock that only needs to generate and output the demanded control signal in a regular manner, there is no doubt that a considerable amount of wafer area can be saved. And then, the consumed power, even the generated heat, is strongly reduced correspondingly. In some processed simulation, both the occupied wafer area and the energy consumption may be reduced by approximately 50%. Furthermore, as well-known, the occupied wafer area and the consumed energy of the PLL is proportional the output frequency of the VCO electrically coupled with the PLL. Hence, the benefits are more significant when the combination of the PLL and the VCO is used to output signal with higher frequency. In some processed simulations, the benefits of the invention are dramatically enhanced when the required frequency is greater than 20 GHZ.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method of utilizing a VCO to continuously provide a signal at an acceptable frequency during an operation period of the VCO, comprising:
initializing the VCO so that the VCO outputs a specific signal at a specific frequency;
operating the VCO on its own for a specific period; and
at the end of the specific period, inputting a control signal to the VCO to modify the operation of the VCO, wherein the control signal is designed to make the VCO output the specific signal at the specific frequency.

2. The method according to claim 1, further comprising adjusting the capacitance of at least one capacitor of the VCO so as to make the VCO output the specific signal before the VCO operates on its own for the specific period.

3. The method according to claim 1, wherein the VCO is operated without receiving any control signal during the specific period.

4. The method according to claim 1, further comprising repeating the step of operating the VCO on its own for a specific period and the step of inputting a control signal to the VCO to modify the operation of the VCO at the end of the specific interval in a regular manner.

5. The method according to claim 4, further comprising at least one of the following:
adjusting the specific period of operating the VCO after the operation of the VCO has been modified according to the control signal and before the VCO operates on its own again; and
adjusting the control signal after the VCO has operated on its own again and before the operation of the VCO is modified again.

6. The method according to claim 1, wherein the control signal is a square wave, wherein the strength of the square wave is proportional to the frequency of the specific signal, and wherein the width of the square wave is proportional to the strength of the specific signal, wherein output power of the VCO gradually enters a steady state as the time gets longer.

7. The method according to claim 1, wherein the control signal is a series of square waves, wherein the strength and the width of each square wave are proportional to the frequency and the strength of the specific signal respectively, and wherein output power of the VCO gradually enters a steady state as the time gets longer.

8. The method according to claim 7, further comprising at least one of the following:
different square waves having different strengths;
different square waves having different widths; and
different time periods between different square waves are non-consistent.

9. A frequency synthesizer capable of generating a specific signal at a specific frequency without utilizing a phase lock loop, comprising:
an injection lock module, configured to receive an input signal and then generate a control signal correspondingly; and
a VCO, configured to receive the control signal and then output an output signal correspondingly;
wherein the output signal is not feedback to the injection lock module for generating the control signal correspondingly.

10. The frequency synthesizer according to claim 9, wherein the injection lock module is configured to generate the control signal as a series of square waves, wherein the strength and the width of each of these square waves are proportional to the frequency and the strength of the specific signal respectively, also wherein output power of the VCO gradually enters a steady state as the time gets longer.

11. The frequency synthesizer according to claim 10, wherein the injection lock module is configured to utilize the pulse width modulation technology to convert the input signal into the control signal as a series of square waves.

12. The frequency synthesizer according to claim 10, wherein the injection lock module comprises a phase shifter and a XOR gate, wherein the phase shifter is configured to delay the phase of the input signal by a specific delay period for generating an additional signal, and wherein the XOR gate is configured to receive both the input signal and the additional signal and then correspondingly generates the control signal to be inputted to the VCO.

13. The frequency synthesizer according to claim 12, wherein the specific delay period is inversely proportional to the specific frequency of the specific signal.

14. The frequency synthesizer according to claim 9, c a counter and a controller, wherein the counter is configured to detect the frequency of a signal outputted by the VCO when the VCO is initialized, wherein the controller is configured to adjust the capacitance of at least one capacitor of the VCO so as to modify the initialization of the VCO to generate the specific signal at the specific frequency, wherein the injection lock module is configured to generates a series of square waves so as to modify the operation of the VCO during the operation period of the VCO correspondingly, wherein the strength and the width of each of these square waves is proportional to the specific frequency and the strength of the specific signal respectively when output power of the VCO gradually enters a steady state as the time gets longer, and wherein the controller is configured to modify operation of the injection lock module so as to adjust the width of each of these square waves.

15. A method of utilizing a frequency synthesizer without phase lock loop to continuously provide a signal at acceptable frequency during an operation period, comprising:
utilizing an injection lock module to receive an input signal and then generate a control signal correspondingly; and
utilizing a VCO to receive the control signal and then output an output signal correspondingly;
wherein the output signal is not feedback to the injection lock module for generating the control signal correspondingly.

16. The method according to claim 15, further comprising utilizing the injection lock module to generate the control signal as a series of square waves, wherein the strength and the width of each of these square waves are proportional to the frequency and the strength of the specific signal respectively, and wherein output power of the VCO gradually enters a steady state as the time gets longer.

17. The method according to claim 15, further comprising the injection lock module utilizes the pulse width modulation technology to convert the input signal into the control signal as a series of square waves, wherein the strength and the width of each of these square waves are proportional to the frequency and the strength of the specific signal respectively, and wherein output power of the VCO gradually enters a steady state as the time gets longer.

18. The method according to claim 15, further comprising the injection lock module utilizes a phase shifter to delay the phase of the input signal by a specific delay period for generating an additional signal, and further comprising the injection lock module utilizes an XOR gate to receive both the input signal and the additional signal and then outputs the control signal to the VCO.

19. The method according to claim 18, further comprising the specific delay period is inversely proportional to the required frequency of the specific signal.

20. The method according to claim 15, further comprising:
utilizing a counter to detect the frequency of a signal outputted by the VCO when the VCO is initialized;
utilizing the controller to adjust the capacitance of at least one capacitor of the VCO so as to modify the initialization of the VCO to generate the specific signal at the specific frequency;
utilizing the injection lock module to generates a series of square waves so as to modify the operation of the VCO during the operation period of the VCO correspondingly, wherein the strength and the width of each of these square waves is proportional to the specific frequency and the strength of the specific signal respectively, and wherein output power of the VCO gradually enters a steady state as the time gets longer; and
utilizing the controller to modify the operation of the injection lock module so as to adjust the width of each of these square waves.
